(19) United States
(12) Patent Application Publication
(10) Pub. No.: US 2012/0171362 A1
(43) Pub. Date: Jul. 5, 2012

(54) HYDROCARBON ADHESIVE COMPOSITION AND METHOD FOR TREATING SUBSTRATE SURFACE USING SAME

(75) Inventors: Young Hoon Kim, Yongin-si (KR); Min Su Lee, Suwon-si (KR); Yong Wook Kim, Yongin-si (KR)

(73) Assignee: DOOSAN CORPORATION, Seoul (FR)

(21) Appl. No.: 13/382,060

(22) PCT Filed: Dec. 14, 2009
(86) PCT No.: PCT/KR09/07242

§ 371 Date: Mar. 22, 2012

(30) Foreign Application Priority Data
Jul. 3, 2009 (KR) 10-2009-0060446

(51) Int. Cl. H05K 3/10; C09J 163/10

(52) U.S. Cl. 427/98.5; 523/437

(57) ABSTRACT

Disclosed are a non-fluorine and non-silicon hydrocarbon-based adhesive composition for substrate surface treatment for inkjet printing, a substrate surface-treated by the composition, and a method for modifying the surface of the substrate by using the composition so as to form fine lines by means of inkjet nano ink. The disclosed composition includes only an epoxy resin, or includes an epoxy resin and an acrylic compound, so as to hydrophobically modify the substrate. The composition can achieve better properties such as an increase in an ink contact angle, an ink spreadability inhibiting effect, and a wiring adhesive strength, as compared to a conventional silicon-based and/or fluorinated adhesive. Furthermore, since a conventional silicon-based and fluorinated adhesive component is not used, it is possible to perform substrate surface treatment in terms of environmental safety, thereby improving the productivity and the economic efficiency.

### TECHNICAL FIELD

The present invention relates to a hydrocarbon-based adhesive composition for environmentally friendly surface treatment, a method for modifying the surface of a substrate by using the composition, and a method forming a fine pattern, in which the composition can improve the adhesive strength with the substrate and inhibit the spreadability of ink, during formation of printed wiring through an inkjet method.

### BACKGROUND ART

In order to form wiring on a substrate, a corrosion resistant method has been conventionally used. However, the method has a disadvantage in that it causes a large loss of material, is complicated in its process, and discharges a large amount of environmentally harmful materials.

An inkjet method in which any pattern can be easily printed in a non-contact manner has been recently employed in circuit formation for electronic parts because it has advantages such as process simplicity, a low cost, mass production capability, and is less harmful to the environment.

In the inkjet method, in the realization of a fine pattern, there are important factors such as a nozzle size control, a discharged ink drop size control, and ink spreadability on a substrate. Herein, it is difficult to reduce the nozzle size or the ink drop size. For example, when inkjet patterning is performed by spraying ink on an untreated substrate from a 50 μm nozzle, a diameter of a drop of ink discharged from the nozzle is increased approximately 1.5 times. Then, when dropping on the untreated substrate, the drop is further spread to a size several times larger. Thus, there is a problem in that the width of a fine pattern (wiring) is increased approximately several times as compared to the spray nozzle. Accordingly, it is important to control the spreadability of an ink drop on a substrate.

Meanwhile, there is a method for controlling the spreadability and the wettability of a discharged drop by modifying chemical and physical properties of a substrate through surface treatment. In such surface treatment, a silicon-based or fluorinated adhesive composition has been mainly used.

Korean Registered Patent No. 10-0783471 discloses ink spreadability control using a silicon adhesive. However, when such an adhesive is used for surface treatment of a substrate, an environmentally harmful material is required. Furthermore, silicon's own swelling may cause a problem in the reliability of the substrate.

Also, in another method, after fluorine-coating, a substrate is treated with UV-ozone (O₃) so as to control the hydrophobicity and the hydrophilicity. However, like the above method, a large amount of environmentally harmful materials are discharged, and also it is required to perform hydrophilic treatment after hydrophobic treatment. This causes a productivity reduction according to an increase of the number of processes.

Accordingly, it is required to develop a surface treatment which can improve the productivity and economic efficiency due to simplicity of a surface treatment process of a substrate, inhibit the spreadability of ink, and which is environmentally friendly.

### DISCLOSURE

### Technical Problem

In order to solve the problems of a conventional technology and the environmental problems, the inventors of the present invention performed surface treatment of a substrate by using a hydrocarbon-based adhesive composition, in which the composition includes a non-fluorine and non-silicon hydrocarbon-based adhesive, e.g., an epoxy resin, or an epoxy resin and an acrylic compound, as an active component. As a result, they found that it is possible to realize a fine pattern and to secure an adhesive property with a substrate by inhibiting the spreadability of ink, and completed this invention based on this finding.

An object of the present invention is to provide a hydrocarbon-based adhesive composition for surface treatment, a method for surface-treating a substrate by using the composition, and a method forming a fine pattern, in which the composition can improve the adhesive strength with the substrate and inhibit the spreadability of ink in the substrate, during formation of a pattern through an inkjet method.

### Technical Solution

In accordance with an aspect of the present invention, there is provided a hydrocarbon-based adhesive composition for substrate surface treatment for inkjet printing, including: (a) a non-fluorine and non-silicon hydrocarbon-based epoxy resin; (b) a non-fluorine and non-silicon hydrocarbon-based acrylic compound; (c) at least one kind additive selected from the group including a dispersant and a surfactant; (d) a curing agent; and (e) a solvent, wherein (b) the non-fluorine and non-silicon hydrocarbon-based acrylic compound includes an acrylic compound that is unsubstituted with a hydrogen bondable substituent and has 6˜22 carbon atoms, in an amount of 30 parts by weight or more with respect to 100 parts by weight of the non-fluorine and non-silicon hydrocarbon-based acrylic compound.

In accordance with another aspect of the present invention, there is provided a hydrocarbon-based adhesive composition for substrate surface treatment for inkjet printing, including: a non-fluorine and non-silicon hydrocarbon-based epoxy resin; a curing agent; and a solvent, wherein the non-fluorine and non-silicon hydrocarbon-based epoxy resin includes three or more kinds of epoxy resins having different numbers (n) of repeating units per molecule.

Herein, the adhesive composition may further include non-fluorine and non-silicon-based rubber.

In accordance with a further aspect of the present invention, there is provided a substrate surface-treated by the above described hydrocarbon-based adhesive composition for substrate surface treatment

In accordance with a still further aspect of the present invention, there is provided a method for forming a fine pattern of printed wiring through an inkjet method, the method including the steps of: (a) surface-treating a substrate by coating a coating liquid including the hydrocarbon-based adhesive composition on at least one surface of the substrate, followed by heat treatment; and (b) forming wiring on the surface-treated substrate by using metal ink including conductive particles.

Herein, in the method, an inkjet pattern is formed by using the metal ink in a state where the hydrocarbon-based adhesive composition including only an epoxy resin is half-cured.

Herein, when the composition is half-cured, there is no solvent in the epoxy resin, and OH groups are not generated on an epoxy surface yet. In other words, the half-cured state indicates the curing reaction has been proceeded up to 10 to 80% (see Reaction Scheme 2).

### Advantageous Effects

The composition according to the present invention can achieve better properties such as an increase in an ink contact angle, an ink spreadability inhibiting effect, and a wiring adhesive strength, as compared to a conventional silicon-based and/or fluorinated adhesive. Furthermore, in the present invention, since a conventional silicon-based and fluorinated adhesive component is not used, it is possible to perform substrate surface treatment in terms of environmental safety, thereby improving the productivity and the economic efficiency.

### BEST MODE

### Mode for Invention

Hereinafter, exemplary embodiments of the present invention will be described.

In a pattern forming process using an inkjet method, factors having an effect of the spreadability of ink are the characteristic of the ink, the size and concentration of metal particles included in the ink, a nozzle size, the size or surface tension of a discharged drop, a surface energy of a substrate, etc.

The present invention provides a hydrocarbon-based adhesive composition which can adjust a contact angle of ink to a predetermined range through hydrophobic treatment of a substrate, inhibit the spreadability of ink by inhibiting the physical and chemical bonds between the ink (e.g., aqueous ink) and a substrate surface, and inhibit the aggregation caused by overlapping between ink drops.

Such spreadability of ink may be measured by measuring the contact angle of a drop discharged on the surface of a substrate, and the wiring width of printed wiring.

The inventive hydrocarbon-based adhesive composition may be realized in two embodiments, which will be described in detail below.

According to a first embodiment of the present invention, a hydrocarbon-based adhesive composition includes only an epoxy resin as a resin component, in which three or more kinds of epoxy resins having different degrees of polymerization (n) are used in combination.

In other words, when epoxy resins having different degrees of polymerization (n) or different equivalents are used in combination, a density difference of a polymer is caused, thereby varying the shape of a pattern. Thus, the degree of cure is varied, while contact angles can have different values.

The hydrocarbon-based adhesive composition includes: (a) a non-fluorine and non-silicon hydrocarbon-based epoxy resin including epoxy resins having different numbers (n) of repeating units, (c) a curing agent and (d) a solvent, and may selectively further include (b) non-fluorine and non-silicon-based rubber.

There is no specific limitation in the epoxy resin (a) as long as it is a general epoxy resin that does not contain fluorine or silicon. Preferably, it is an epoxy compound containing two or more epoxy groups per molecule.

Non-limiting examples of an epoxy resin that may be used in the present invention may include an epoxy resin obtained through epoxidation of a condensate between phenol or alkyl phenol and hydroxybenzaldehyde, a phenol novolak type epoxy resin, a cresol novolak type epoxy resin, a phenolaralkyl type epoxy resin, a biphenyl type epoxy resin, a bisphenol A type epoxy resin represented by Formula 1 below, a bisphenol F type epoxy resin, a linear aliphatic epoxy resin, an alicyclic epoxy resin, a heterocyclic epoxy resin, a spiro ring-containing epoxy resin, a xylok type epoxy resin, a multifunctional epoxy resin, a novolak epoxy resin represented by Formula 2 below, a naphthol novolak type epoxy resin, a bisphenol A/bisphenol F/bisphenol AD novolak type epoxy resin, a bisphenol A/bisphenol F/bisphenol AD glycidyl ether, a bishydroxybiphenyl-based epoxy resin, a dicyclopentadiene-based epoxy resin, a naphthalene-based epoxy resin, a flame retardant epoxy resin, a cyclic epoxy resin, a rubber modified epoxy resin, an aliphatic polyglycidyl type epoxy resin, a glycidyl amine type epoxy resin, a mixture thereof, etc.

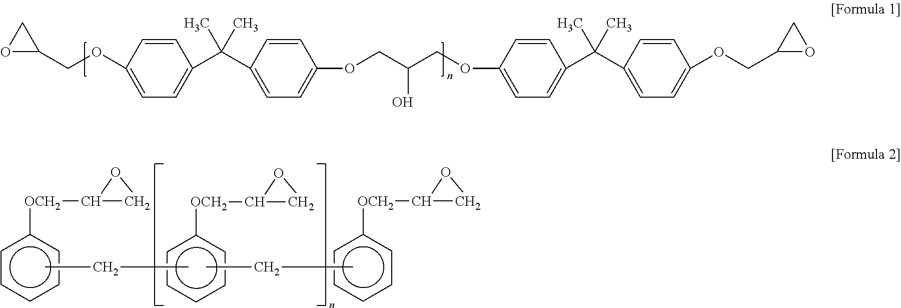

In Formulas 1 and 2, the average of the numbers (n) ranges from 0.1 to 30.

It is preferable that the epoxy resin has a high glass transition temperature (T_{g}). For example, the temperature may range from 80 to 250° C., or from 90 to 200° C. Also, epoxy resins may have an equivalent difference ranging about from 100 to 600, but the present invention is not limited thereto.

The epoxy resin may be used in an amount of 10 to 80 parts by weight with respect to 100 parts by weight of the total hydrocarbon-based adhesive composition. Also, it may be used in an amount of 10 to 50 parts by weight, preferably 10 to 30 parts by weight.

Meanwhile, as the average of numbers (n) of repeating units of the epoxy resins is increased, the amount of OH groups bonded to carbon, as shown in Reaction Scheme 2 below, is increased. Then, the OH groups chemically bonded to an organic solvent (e.g., ether, alcohol) included in ink. This decreases an ink contact angle, while improving a molecular weight, a flexibility, and an impact resistance of the resin. Meanwhile, when the number n is decreased, some properties such as a compressive strength and a chemical resistance can be improved. Thus, it is important to determine an appropriate value for n. In the present invention, the number n of the epoxy resin may range from 0.1 to 30, preferably 0.1 to 15.

Specific examples of an epoxy resin that may be used in the present invention may include bisphenol A (n: 1˜2, shinhwa T&C, 500R), bisphenol A (n: 0.12˜0.13, kukdo chemical, YD-128), bisphenol A (n: 0.15˜0.16, kukdo chemical, YD-134), bisphenol A (n: 2.1˜2.2, kukdo chemical, YD-011), bisphenol A (n: 5.4˜5.5, kukdo chemical, YD-014), bisphenol A (n: 11.0˜12.0, kukdo chemical, YD-017) and the like.

The epoxy resins may be used in a ratio of bisphenol A (ShinHwa T&C 500R) 0˜50 : bisphenol A (kukdo chemical YD-128) 50˜90: bisphenol A (kukdo chemical YD-014) 0˜30: bisphenol A (kukdo chemical YD-017) 0˜10: bisphenol A (kukdo chemical, YD-134) 5˜50 (weight ratio), but the present invention is not limited thereto. Herein, it is preferable that bisphenol A (n: 0.12˜0.13, YD-128), bisphenol A (n: 0.1˜0.16, YD-134) and bisphenol A (n: 11.0˜12.0, YD-017) are used in combination. Herein, the ratio of these materials may be appropriately adjusted within a range of 50˜90: 5˜40: 0.1˜10 (weight ratio).

The hydrocarbon-based adhesive composition may further include rubber (b). Herein, the rubber may include natural rubber, synthetic rubber or a combination thereof. The rubber performs a role of providing flexibility to a primer layer when a substrate has flexibility.

Non-limiting examples of rubber (b) that may be used in the present invention may include acrylonitrile butadiene rubber (NBR), styrene butadiene rubber, butadiene rubber, butyl rubber, halogenated butyl rubber, isoprene-containing styrene butadiene rubber, nitrile-containing styrene butadiene rubber, neoprene rubber, chloroprene rubber, isobutyl isoprene rubber, ethylene propylene diene rubber, chloro butyl rubber, bromo butyl rubber, and a mixture thereof.

The rubber may be used in an amount of 0 to 20 parts by weight with respect to 100 parts by weight of the total hydrocarbon-based adhesive composition, preferably 0 to 10 parts by weight.

The amount of the curing agent (c) may be adjusted according to a resin solid content within the hydrocarbon-based adhesive composition. For example, the curing agent may be added in an amount of 5˜20 parts by weight with respect to 100 parts by weight of the solid content. Non-limiting examples of the curing agent that may be used in the present invention may include an ambient temperature amine-based curing agent, a high temperature organic acid anhydride-based curing agent, an aliphatic polyamine-based (diethylenetriamine, triethylenetetramine, and the like) curing agent, and a mixture thereof. An ambient temperature curing agent is preferred.

Besides, examples of the polyamine may include metaphenylenediamine, diaminodiphenylmethane, diaminodiphenylsulfone, and the like, and examples of an acid anhydride-based curing agent may include phthalic anhydride, tetra- and hexahydrophthalic anhydride that can be easily handled due to a low melting point, methyltetrahydro phthalic anhydride that has a property balance in a liquid state, and is relatively inexpensive, liquid methyl nadic anhydride with a long pot life, pyromellitic dianhydride with a high temperature property, flame retardant HET anhydride, dodecenyl succinic anhydride for providing flexibility, and the like.

As the solvent (d), general solvents known in the art, which have been conventionally used for substrate surface treatment, may be used without limitations. For example, an aromatic hydrocarbon solvent such as xylene, toluene, pyridine, quinoline, anisole, and mesitylene, and an aliphatic hydrocarbon solvent such as hexane and hectane may be used in combination.

The amount of the solvent may be adjusted accordingly to a total 100 parts by weight of the inventive hydrocarbon-based adhesive composition. For example, it may be used in an amount of 20 to 70 parts by weight or of 20 to 60 parts by weight with respect to 100 parts by weight of the adhesive composition, but the present invention is not limited thereto.

According to a second embodiment of the present invention, a hydrocarbon-based adhesive composition includes an epoxy resin and an acrylic compound in combination, in which the acrylic compound includes a predetermined amount of an acrylic compound that is unsubstituted with a hydrogen bondable functional group (—OH, —NH, —SH) and has 6˜22 carbon atoms.

Conventional ink, e.g., aqueous ink, includes TGME (Tri-ethylene Glycol Mono-ethyl Ether) as organic matter, and ether or alcohol such as Terpineol. Herein, in the present invention, when a substituent capable of being easily hydrogen bonded to ether and alcohol, for example, a monomer or polymer compound not containing —OH, —NH, —SH group, is used (see Reaction Scheme 2), it is possible to inhibit the adsorption of organic matter used in ink, and to improve the repulsive force with a hydrophilic material.

The hydrocarbon-based adhesive composition includes (a) a non-fluorine and non-silicon hydrocarbon-based epoxy resin, (b) a non-fluorine and non-silicon hydrocarbon-based acrylic compound, (c) a dispersant, a surfactant, or a mixture thereof, (d) a curing agent, and (e) a solvent. The non-fluorine and non-silicon hydrocarbon-based acrylic compound may include an acrylic compound that is unsubstituted with a hydrogen bondable functional group (—OH, —NH, —SH) and has 6˜22 carbon atoms, in an amount of 30 or more parts by weight with respect to 100 parts by weight of the total acrylic compound.

Non-limiting examples of the acrylic compound that does not contain the hydrogen bondable functional group (e.g., —OH, —NH, —SH), and has 6˜22 carbon atoms may include BMA (butylacrylate), SMA (stearyl methacrylate), MMA (methylmethacrylate), a mixture thereof, and the like. Herein, the acrylic compound unsubstituted with the hydrogen bondable functional group may be used in an amount of 30 to 80 parts by weight with respect to 100 parts by weight of the total acrylic compound. For example, at least one kind of an acrylic compound such as SMA and MMA may be used in an amount of 30 or more parts by weight.

As the epoxy resin (a), a general epoxy resin known in the art may be used without limitations, and examples of the epoxy resin may be the same as those previously described above. For example, a novolak type epoxy resin may be used. Herein, the epoxy resin may be used in an amount of 10 to 50 parts by weight or 10 to 40 parts by weight with respect to 100 parts by weight of the composition, but the present invention is not limited thereto.

Besides the acrylic compound unsubstituted with a hydrogen bondable substituent, the inventive acrylic compound (b) may include general acrylic compounds not containing fluorine and silicon without limitation.

Herein, non-limiting examples of the non-fluorine and non-silicon hydrocarbon-based acrylic compound that may be used in combination with the acrylic compound unsubstituted with the hydrogen bondable functional group may include glycidyl methacrylate (GMA), 2-hydroxyethyl methacrylate (HEMA), ethyl acrylate, propylacrylate, isopropyl acrylate, isobutyl acrylate, n-amyl acrylate, isoamyl acrylate, n-hexyl acrylate, 2-ethylhexyl acrylate, hydroxyethyl acrylate, hydroxypropyl acrylate, lauryl acrylate, ethyl methacrylate, propyl methacrylate, isopropyl methacrylate, n-butyl methacrylate, isobutyl methacrylate, n-amyl methacrylate, isoamyl methacrylate, n-hexyl methacrylate, 2-ethylhexyl methacrylate, hydroxyethyl methacrylate, hydroxypropyl methacrylate, lauryl methacrylate, allyl methacrylate, and the like.

Herein, the acrylic compound unsubstituted with the hydrogen bondable functional group and the general acrylic compound may be used in a weight ratio of 40˜60: 60˜40, preferably 50:50 with respect to 100 parts by weight of the total acrylic compound.

The above described acrylic compound may be used alone or in combination of two or more kinds thereof. Herein, it may be used in an amount of 30 to 60 parts by weight with respect to 100 parts by weight of the total hydrocarbon-based adhesive composition, but the present invention is not limited thereto.

The epoxy resin (a) and the acrylic compound (b) may be polymerized to form a copolymer including a repeating unit, represented by Formula 3 below.

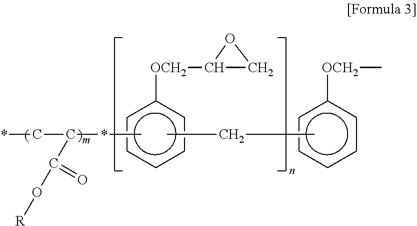

In Formula above,

R represents a linear-, branched-, or cyclicaliphatic, cycloaliphatic or aromatic alkyl group, aryl group or allyl group, which is unsubstituted with a hydrogen bondable functional group and has 6 to 22 carbon atoms, and

n ranges from 1 to 30, and m ranges from 1 to 20.

In the copolymer represented by Formula 3 above, the position next to a carbonyl group is substituted with an alkoxy (—OR) functional group, wherein as R, a typical hydrophobic group, such as a linear or cyclic aliphatic or aromatic alkyl group, may be introduced to provide hydrophobicity. More specifically, R may represent an aliphatic or aromatic substituent having 6˜22 carbon atoms. For example, R may be a propyl group, a butyl group, a hexyl group, an octyl group, a decyl group, a dodecyl (lauryl) group, a cetyl group, a stearyl group, a behenyl group, or the like.

Also, when the difference (ΔS) of solubility between the copolymer and aqueous ink or a diluent (TGME) included in the aqueous ink is adjusted in a range of ±5.0 to 5.5, it is possible to achieve an appropriate contact angle with ink, appropriate ink spreadability, and an adhesive strength. Herein, the solubility of TGME

$$[ δ ( \sqrt{\frac{cal}{{cm}^{3}}} ) ]$$

may be 9.1.

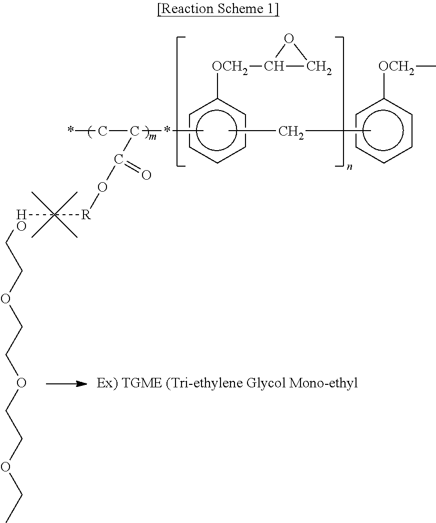

The inventive hydrocarbon-based adhesive composition may include a compound for increasing the hardness of a coating layer, added to the above described acrylic compound. There is no limitation in the compound for increasing the hardness of the coating layer as long as it has an aromatic ring. For example, it may be a styrene monomer, or the like. There is no specific limitation in the amount of the styrene monomer. For example, the styrene monomer may be included in an amount of 10 to 20 parts by weight with respect to 100 parts by weight of the total of the acrylic compound and the styrene monomer. Also, the above described acrylic compounds may be included with respect to 100 parts by weight of the total of the acrylic compounds and the styrene monomer.

The inventive hydrocarbon-based adhesive composition may include a dispersant, a surfactant, or other additives.

The surfactant may perform a role of reducing the surface tension of the composition. Non-limiting examples of the surfactant that may be used in the present invention may include alkylbenzene sulfonate, amine halide, quaternary ammonium salt, alkyl pyridinium salt, amino acid and a mixture thereof.

Also, as the dispersant, a general dispersant known in the art may be used without limitation. For example, a carboxylic acid based material, a thiol based material, a phenol based material, an amine based material or a combination thereof may be used. The dispersant may be used in an amount of 0 to 5 parts by weight with respect to the 100 parts by weight of the composition, but the present invention is not limited thereto.

The amounts of the surfactant and the dispersant are not particularly limited, and may be adjusted within a conventional range known in the art. For example, the surfactant and the dispersant each may be used in an amount of 0 to 5 parts by weight with respect to 100 parts by weight of the composition, respectively. Also, the total of these may be within a range of 0 to 5 parts by weight with respect to 100 parts by weight of the composition.

As the curing accelerator, tertiary amine (benzyldimethylamine), imidazoles, and the like are used alone or in combination. Also, a low temperature fast-curing polymercaptan, and the like may be used. Herein, there is no limitation in the curing accelerator. For example, it may be used in an amount of 0.5 to 3.0 parts by weight with respect to 100 parts by weight of the composition.

The inventive hydrocarbon-based adhesive composition, as required, may further include a releasing agent, a coloring agent, a coupling agent, a stress reliever, or the like, within the scope of the present invention.

The above described hydrocarbon-based adhesive composition may be used for substrate surface treatment for printed wiring formation. According to a preferred embodiment, the surface treatment may be performed by coating a coating liquid including the above described hydrocarbon-based adhesive composition on at least one surface of a substrate, followed by heat treatment.

As the substrate, any substrate used for printed wiring formation may be used without limitation. For example, a polymer substrate may be used. Non-limiting examples of the polymer substrate that may be used in the present invention may include an epoxy substrate, a polyimide substrate, a BT resin substrate, a PET substrate, a PP substrate, a PC substrate or a substrate made of a mixture of these substrate materials.

The coating liquid may be coated by one method selected from the group including spin coating, knife coating, Gravure roll coating and casting, but the present invention is not limited thereto.

Herein, the hydrocarbon-based adhesive coating layer formed on the substrate has a thickness ranging from 0.1 to 30 μm, but the present invention is not limited thereto. Also, in the heat treatment step, the temperature and the time are not particularly limited.

For example, the coating liquid may be dried at 100˜120° C. for 3 to 10 minutes, and then cured at 150˜170° C. for 1 to 70 minutes.

Furthermore, the present invention provides a method for forming a fine pattern of metal wiring on the substrate surface-treated as described above by an inkjet method.

According to one embodiment, the fine pattern forming method may include the steps of forming wiring on the surface-treated substrate by using metal ink including conductive particles, and heat-treating the substrate.

Herein, when the hydrocarbon-based adhesive composition including only an epoxy resin, according to the first embodiment, is used to surface-treat a substrate, the mechanism represented by Reaction Scheme 2 below may be performed.

In other words, after the hydrocarbon-based adhesive composition or a surface treatment composition liquid including the composition is completely cured, —

OH groups are formed in a large amount on the surface of the substrate and distributed in aqueous ink. This reduces a contact angle to less than 20° or less. In a state where the surface treatment composition liquid is completely cured, the spreadability of ink may be highly increased. Thus, it is preferable to perform inkjet wiring patterning by metal ink in a state where the surface treatment composition liquid is half-cured.

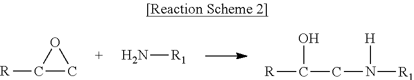

Herein, R represents an epoxy structure, and is the same as described above.

Meanwhile, in the hydrocarbon-based adhesive composition including an epoxy resin and an acrylic compound, according to the second embodiment, it is appropriate that after the adhesive composition is completely cured, wiring is formed by metal ink.

Herein, conductive particles included in the metal ink may include metal nano particles made of at least one material selected from the group including silver (Ag), copper (Cu), gold (Au), platinum (Pt), nickel (Ni), palladium (Pd), iron (Fe) and an alloy thereof. The size of such metal nano particles shows a tendency to be decreased so as to form fine wiring. The size may range from 5 to 50 nm, and preferably from 15 to 30 nm.

The metal ink including the conductive particles may be manufactured by a conventional method in the art. The metal ink is divided into aqueous and non-aqueous inks according to the characteristic of a solvent. Non-limiting examples of the aqueous ink solvent may include diethylene glycol butyl ether acetate, an ethanol aqueous solution, ethylene glycol, or a mixture thereof. The non-aqueous ink solvent may be at least one selected from the group including hexane, octane, tetradecane, hexadecane, 1-hexadecene, 1-octadecene, toluene, xylene and chlorobenzoic acid, but the present invention is not limited thereto.

The method for forming wiring by such metal ink may include screen printing, Gravure printing, inkjet printing, or the like. Especially, an inkjet printing method is preferred to form fine wiring. When the metal ink is discharged by an inkjet method to form wiring, it is possible to form fine wiring having a wiring width ranging from 10 to 80 μm.

The substrate on which wiring is formed is subjected to heat treatment so as to form bonds between metal particles. Such heat treatment is preferably performed under a condition for providing high electrical conductivity to wiring. For example, the heat treatment of ink wiring may be performed at a temperature ranging from 150 to 200° C. for 30 to 60 minutes.

In a conventional method for forming wiring, especially, fluorine coating has a strong repulsive force with ink. Thus, after ink is dropped, there is no force for providing adhesive strength with a substrate at all. For this reason, when ink dots are overlapped during inkjetting, a force between ink dots is stronger than a force between a substrate and ink. Then, aggregation occurs in the ink dots, which reduces the edge sharpness of wiring. In order to inhibit the defect, an ink-aggregation inhibiting method for drying ink to some extent right after ink-dropping by raising the temperature of a substrate has been conventionally frequently used. However, this method has a problem in productivity and size enlargement, and generally causes choking of a nozzle due to a short distance between the nozzle and a substrate.

On the other hand, in the present invention, since the non-fluorine and non-silicon hydrocarbon-based adhesive is coated on the substrate, there is no need to heat the substrate. Furthermore, in a state where ink is wet, it is possible to achieve a high edge sharpness due to adhesive strength.

Hereinafter, the present invention will be described more specifically with reference to the following examples. The following examples are only for illustrative purposes and are not intended to limit the scope of the invention.

### EXAMPLE 1

### Preparation of Hydrocarbon-Based Adhesive Composition (1)

As a curing agent, polyamide was used in an amount of 10 parts by weight with respect to the resin solid content, and as an epoxy resin, Novolac Type (Glycidyl Methacrylate, GMA) was fixedly used in an amount of 30 parts by weight. Other components were used in a combination ratio noted in Table 1 below, in an amount of 70 parts by weight (converted into 100 parts by weight). Then, an acryl monomer composition was obtained.

Meanwhile, adhesive compositions of Comparative Examples 1˜3 according to the combination ratios noted in Table 1 below were prepared. According to the amounts of SMA and MMA as acrylic compounds, the contact angle characteristics on Di-water, Formamide, and Ag ink (35 dyne/cm) were tested. As a result, it can be found that when the adhesive composition including SMA and MMA in large amounts, from Example 1, is used, it is possible to achieve a contact angle of 40° or more and the lowest surface energy. Meanwhile it is known that the best printed-pattering can be achieved when a contact angle ranges from 40 to 60°.

TABLE 1

| | Example | | | | | | | |
|---|---|---|---|---|---|---|---|---|
| | | | Comparative | | Comparative | | Comparative | |
| | Example 1 | | Example 1 | | Example 2 | | Example 3 | |
| Chemical comp. | Epoxy | | Epoxy | | Epoxy | | Epoxy | |
| | acrylate | | acrylate | | acrylate | | acrylate | |
| solid content (%) | 20 | | 20 | | 20 | | 20 | |
| pH | 7 | | 7 | | 7 | | 7 | |
| Viscosity (cps.) | 100 or less | | 100 or less | | 100 or less | | 100 or less | |
| T_{g} (° C.) | 70 | | 65 | | 65 | | 50 | |
| molecular weight | 55,000 ± 1,500 | | 20,000 ± 1,500 | | 20,000 ± 1,500 | | 20,000 ± 1,500 | |
| Monomer | SM | (18) | SM | (75) | SM | (75) | SM | (75) |
| | SMA | (28) | SMA | (0) | SMA | (0) | SMA | (0) |
| | GMA | (4) | GMA | (10) | GMA | (12.5) | GMA | (5) |
| | HEMA | (5) | HEMA | (10) | HEMA | (10) | HEMA | (10) |
| | MMA | (45) | MMA | (5) | MMA | (2.5) | MMA | (10) |

| Solvent | | Xylene | Xylene | Xylene | Xylene |
|---|---|---|---|---|---|
| contact | Di-water | 91.8 | 83.4 | 79.3 | 75.3 |
| angle | Formamide | 80.1 | 63.7 | 62.1 | 57.9 |
| | S/Energy | 24.8 | 46.9 | 44.4 | 44.3 |
| | Ag Ink | 41.4 | 10.1 | 8.8 | 8.5 |

### EXAMPLES 2˜3

### Hydrocarbon-Based Adhesive Composition (2)

As epoxy resins, YD-128, YD-134, and YD-017 (shinhwa T&C, and kukdo chemical) were used in a combination noted in Table 2 below to prepare a hydrocarbon-based adhesive composition.

Meanwhile, in Comparative Examples 4˜5, an adhesive composition was prepared in a combination noted in Table 2 below.

By using the prepared compositions, a contact angle of Ag ink was tested according to the curing time. As a result, it was found that as the amount of YD-128 increases and the amount of YD-017 decreases, the contact angle of ink also increases.

Herein, the most important thing is that when a surface treatment composition including an epoxy resin (as a main component) mixed with an NBR resin is half-cured, and there is no hydrophilic group on a surface, it is possible to form an inkjet pattern as a fine pattern.

TABLE 2

| | | | | | Compara- | Compara- |
|---|---|---|---|---|---|---|
| | | | Exam- | Exam- | tive | tive |
| | | n | ple2 | ple 3 | Example 4 | Example 5 |
| Epoxy | YD-128 | 0.12~0.13 | 80 | 80 | 30 | 10 |
| resin | YD-134 | 0.15-0.16 | 10 | 5 | — | — |
| | YD-017 | 11.0~12.0 | 5 | 10 | 70 | 90 |

| | | | | |
|---|---|---|---|---|
| NBR | 5 | 5 | 0 | 0 |

### INDUSTRIAL APPLICABILITY

Although several exemplary embodiments of the present invention have been described for illustrative purposes, those skilled in the art will appreciate that various modifications, additions and substitutions are possible, without departing from the scope and spirit of the invention as disclosed in the accompanying claims.

1-14. (canceled)

15. A hydrocarbon-based adhesive composition for substrate surface treatment, comprising:
a non-fluorine and non-silicon hydrocarbon-based epoxy resin in an amount of 10 to 80 parts by weight;
a non-fluorine and non-silicon-based rubber in an amount of 5-20 parts by weight;
a curing agent in an amount of 5 to 20 parts by weight with respect to 100 parts by weight of a resin solid content; and
a solvent in an amount to balance the adhesive composition to 100 parts by weight.

16. The hydrocarbon-based adhesive composition as claimed in claim 15, wherein the non-fluorine and non-silicon hydrocarbon-based epoxy resin comprises three or more kinds of epoxy resins having different numbers (n) of repeating units per molecule.

17. The hydrocarbon-based adhesive composition as claimed in claim 15, wherein in the epoxy resins, an average of the numbers (n) of the repeating units is adjusted in a range of 0.1 to 30.

18. The hydrocarbon-based adhesive composition as claimed in claim 15, wherein the epoxy resin is selected from the group including a bisphenol A type epoxy resin, a novolak type epoxy resin, a bisphenol F type epoxy resin, a flame retardant epoxy resin, a cyclic epoxy resin, a rubber modified epoxy resin, an aliphatic polyglycidyl type epoxy resin, and a glycidyl amine type epoxy resin.

19. A substrate surface-treated by the hydrocarbon-based adhesive composition for substrate surface treatment as claimed in claim 15,
wherein the hydrocarbon-based adhesive composition comprises (a) a non-fluorine and non-silicon hydrocarbon-based epoxy resin in an amount of 10 to 80 parts by weight;
(b) a non-fluorine and non-silicon-based rubber in an amount of 5˜20 parts by weight;
(c) a curing agent in an amount of 5 to 20 parts by weight with respect to 100 parts by weight of a resin solid content; and
(d) a solvent in an amount to balance the adhesive composition to 100 parts by weight.

20. The substrate surface-treated as claimed in claim 19, wherein the non-fluorine and non-silicon hydrocarbon-based epoxy resin comprises three or more kinds of epoxy resins having different numbers (n) of repeating units per molecule.

21. The substrate surface-treated as claimed in claim 19, wherein in the epoxy resins, an average of the numbers (n) of the repeating units is adjusted in a range of 0.1 to 30.

22. The substrate surface-treated as claimed in claim 19, wherein the epoxy resin is selected from the group including a bisphenol A type epoxy resin, a novolak type epoxy resin, a bisphenol F type epoxy resin, a flame retardant epoxy resin, a cyclic epoxy resin, a rubber modified epoxy resin, an aliphatic polyglycidyl type epoxy resin, and a glycidyl amine type epoxy resin.

23. A method for forming a fine pattern of printed wiring, the method comprising the steps of:
(a) surface-treating a substrate by coating a coating liquid comprising the hydrocarbon-based adhesive composition as claimed in claim 15 on at least one surface of the substrate, followed by heat treatment; and
(b) forming wiring on the surface-treated substrate by using metal ink comprising conductive particles, wherein a pattern is formed by using the metal ink in a state where the hydrocarbon-based adhesive composition as claimed in claim 15 is half-cured, the the hydrocarbon-based adhesive composition comprises (a) a non-fluorine and non-silicon hydrocarbon-based epoxy resin in an amount of 10 to 80 parts by weight;
(b) a non-fluorine and non-silicon-based rubber in an amount of 5˜20 parts by weight;
(c) a curing agent in an amount of 5 to 20 parts by weight with respect to 100 parts by weight of a resin solid content; and
(d) a solvent in an amount to balance the adhesive composition to 100 parts by weight.

24. The method as claimed in claim 23, wherein the non-fluorine and non-silicon hydrocarbon-based epoxy resin comprises three or more kinds of epoxy resins having different numbers (n) of repeating units per molecule.

25. The method as claimed in claim 23, wherein in the epoxy resins, an average of the numbers (n) of the repeating units is adjusted in a range of 0.1 to 30.

26. The method as claimed in claim 23, wherein the epoxy resin is selected from the group including a bisphenol A type epoxy resin, a novolak type epoxy resin, a bisphenol F type epoxy resin, a flame retardant epoxy resin, a cyclic epoxy resin, a rubber modified epoxy resin, an aliphatic polyglycidyl type epoxy resin, and a glycidyl amine type epoxy resin.
